(19) United States
(12) Patent Application Publication
(10) Pub. No.: US 2021/0080495 A1
(43) Pub. Date: Mar. 18, 2021

(54) MULTICHANNEL HIGH INTENSITY ELECTROMAGNETIC INTERFERENCE DETECTION AND CHARACTERIZATION

(71) Applicant: Amber Precision Instruments, Inc., San Jose, CA (US)

(72) Inventor: Hamed Kajbaf, San Jose, CA (US)

(21) Appl. No.: 16/572,519

(22) Filed: Sep. 16, 2019

(51) Int. Cl. G01R 29/08; G01R 31/00; G08B 29/18; H04B 17/318

(52) U.S. Cl. CPC G01R 29/0814; G01R 31/002; H04B 17/318; G08B 29/185; G01R 29/0878

(57) ABSTRACT

A system and method for detecting and characterizing high intensity electromagnetic interference signals uses a multichannel detection unit that includes a threshold-based latch to detect a potential electromagnetic interference signal from received signals based on signal strength, power detector to measure power of the detected potential electromagnetic interference signal and a frequency detector to detect a frequency of the detected potential electromagnetic interference signal. Outputs of the multichannel detection unit are then used to determine characteristics of the detected potential electromagnetic interference signal.

### BACKGROUND OF THE INVENTION

An intentional electromagnetic interference (IEMI) may target electronic systems by transmitting an electromagnetic signal beyond the limits that the systems are designed to tolerate. Since IEMI high intensity signals may still be effective from a distance and through physical barriers, such as walls, these attacks are hard to track and are mostly undetected. The characteristics of a potential burst is usually not known in advance which makes it difficult to plan for an effective mitigation during the design stage.

### SUMMARY OF THE INVENTION

A system and method for detecting and characterizing high intensity electromagnetic interference signals uses a multichannel detection unit that includes a threshold-based latch to detect a potential electromagnetic interference signal from received signals based on signal strength, power detector to measure power of the detected potential electromagnetic interference signal and a frequency detector to detect a frequency of the detected potential electromagnetic interference signal. Outputs of the multichannel detection unit are then used to determine characteristics of the detected potential electromagnetic interference signal.

A high intensity electromagnetic interference detection system in accordance with an embodiment of the invention comprises at least one antenna to receive signals, a multichannel detection unit connected to the at least one antenna to receive the signals, the detection unit including a threshold-based latch to detect a potential electromagnetic interference signal from the received signals based on signal strength, a power detector to measure power of the detected potential electromagnetic interference signal, and a frequency detector to detect a frequency of the detected potential electromagnetic interference signal, and a processor connected to the multichannel detection unit to receive outputs from the multichannel detection unit and process the outputs to determine characteristics of the detected potential electromagnetic interference signal.

A method for detecting and characterizing high intensity electromagnetic interference signals in accordance with an embodiment of the invention comprises receiving signals on at least one antenna, detecting a potential electromagnetic interference signal from the received signals based on signal strength using a threshold-based latch of a multichannel detection unit, measuring power of the detected potential electromagnetic interference signal using a power detector of the multichannel detection unit, detecting a frequency of the detected potential electromagnetic interference signal using a frequency detector of the multichannel detection unit, and processing outputs of the multichannel detection unit to determine characteristics of the detected potential electromagnetic interference signal.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a diagram of a multichannel IEMI detection and characterization (MIDC) system in accordance with an embodiment of the invention.

FIG. 2 is a block diagram of a threshold-based latch of the MIDC system in accordance with an embodiment of the invention.

FIG. 3 is a block diagram of a power detector of the MIDC system in accordance with an embodiment of the invention.

FIG. 4 is a block diagram of a frequency detector of the MIDC system in accordance with an embodiment of the invention.

FIG. 5 is a screenshot of a graphical user interface provided by software installed and running on a control unit of the MIDC system in accordance with an embodiment of the invention.

FIG. 6 a flowchart of the detection, characterization and localization operations of the MIDC system in accordance with an embodiment of the invention.

FIG. 7 shows the narrowband response of the power detector channel of the MIDC system in accordance with an embodiment of the invention.

FIG. 8 shows the narrowband response of the frequency detector channel of the MIDC system in accordance with an embodiment of the invention.

FIG. 9 shows the output voltage of a transmission line pulser (TLP) when connected to a matched load during characterization of the broadband response of the power detector channel of the MIDC system in accordance with an embodiment of the invention.

FIG. 10 shows the broadband response of the power detector channel of the MIDC system in accordance with an embodiment of the invention.

FIG. 11 shows the broadband response of the frequency detector channel of the MIDC system in accordance with an embodiment of the invention.

FIG. 12 shows the maximum exposure field strength during detection capability testing of the MIDC system in accordance with an embodiment of the invention.

FIG. 13 shows the measured E-field in a test configuration where a transmission line pulser (TLP) was connected to a double-ridge horn antenna in accordance with an embodiment of the invention.

FIG. 14 shows the transient E-field at 13 kV/m in another test configuration where a Kentech Instruments PBG1-D pulse generator was connected to a double-ridge horn antenna in accordance with an embodiment of the invention.

FIG. 15 is a block diagram of an antenna array system for source localization in accordance with an embodiment of the invention.

FIG. 16 is a flow diagram of a method for detecting and characterizing electromagnetic interference signals in accordance with an embodiment of the invention.

### DETAILED DESCRIPTION

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment,” “an embodiment,” or similar language means that a particular feature, structure, or characteristic described in connection with the indicated embodiment is included in at least one embodiment of the present invention. Thus, the phrases “in one embodiment,” “in an embodiment,” and similar language throughout this specification may, but do not necessarily, all refer to the same embodiment.

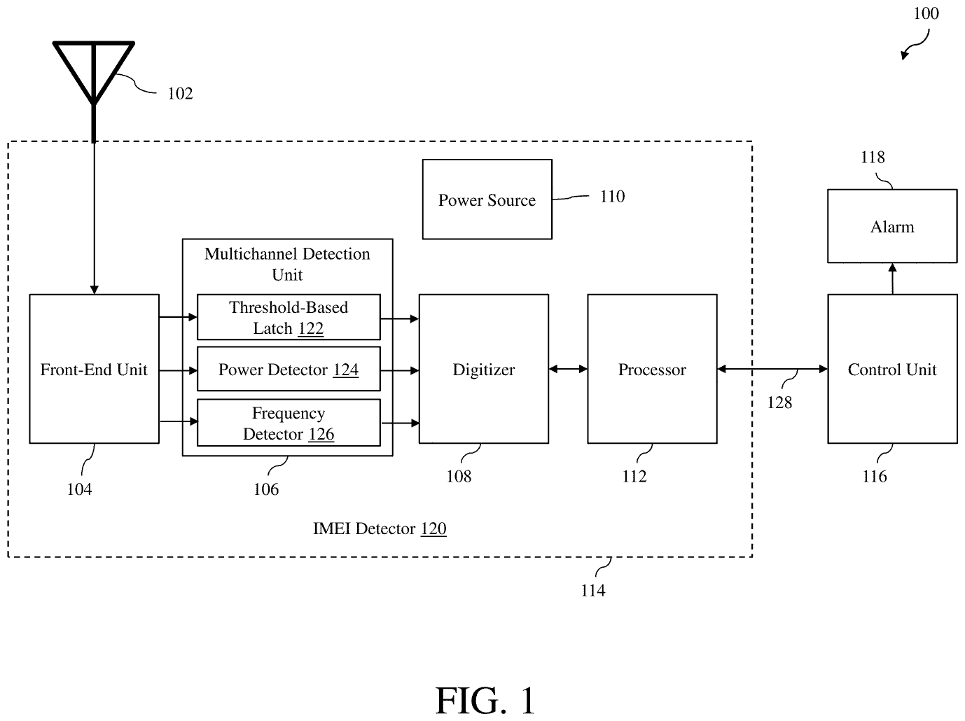

With reference to FIG. 1, a multichannel IEMI detection and characterization (MIDC) system 100 for detecting and characterizing IEMI high intensity signals in accordance with an embodiment of the invention is described. As used herein, “high intensity” signals includes signals with peak value of electric field higher than 1 V/m and may go as high tens of kV/m. The MIDC system 100 is capable of reporting the characteristics of IEMI high intensity signals that can be used to gather statistical information. In particular, the MIDC system is capable of identifying the electromagnetic signal of an IEMI high intensity signal based on frequency, pulse duration, pulse repetition rate, magnitude, and bandwidth without showing any malfunction or degradation of performance due to the high intensity of the IEMI signals. The MIDC system is designed based on a multichannel signal conditioning scheme for an accurate detection with low false alarm rate. Statistical characteristics of the detected signal can then be logged and analyzed.

As shown in FIG. 1, the MIDC system 100 includes an antenna 102, a front-end unit 104, a multichannel detection unit 106, a digitizer 108, a power source 110, and a processor 112. In an embodiment, the front-end unit 104, the multichannel detection unit 106, the digitizer 108, the power source 110, and the processor 112 are encased in an electromagnetic interference (EMI)-shielded box 114, which can be made of a metallic material. The EMI-shielded box 114 ensures that the electronics and data contained in the box are protected from IEMI high intensity signals. The MIDC system 100 further includes a control unit 116 and an alarm 118, which may be outside of the EMI-shielded box 114. Preferably, the control unit 116 and the alarm 118 are remote from the EMI-shielded box 114 so that any IEMI high intensity signals at the location of the EMI-shielded box 114 do not cause damage to the control unit 116 and the alarm 118. The EMI-shielded box 114 with the components contained therein and the antenna 102 will be referred to herein as the “IEMI detector” 120.

The power source 110 is used to supply electrical power to the components in the EMI-shielded box 114 that require power. The power source 110 may include one or more batteries to provide the electrical power. The type of batteries used as the power source 110 can be any type of batteries, such as rechargeable lithium ion batteries.

The antenna 102 is used to receive RF signals of IEMI high intensity signals, which can be short in duration, e.g., tens of picoseconds. The RF signals are transmitted to the frond-end unit 104, which includes RF protection circuit, impedance matching circuit, voltage limiter, attenuator, amplifier, and automatic gain control (AGC) as needed for signal conditioning. The RF protection circuit operates to ensure that the received signals do not overload or damage any downstream electronic components in the system. The impedance matching circuit operates to match the impedance of the received signals at the antenna 102 to the downstream electronic components, such as the multichannel detection unit 106. The RF protection, impedance matching circuits, voltage limiter, attenuator, amplifier, and automatic gain control are well known circuits, and thus, these circuits are not described here in detail. Using these circuits, the frond-end unit 104 can properly receive the IEMI RF signals and transit the RF signals to the multichannel detection unit 106.

The multichannel detection unit 106 receives the RF signals from the frond-end unit 104 to detect an IEMI high intensity signal and to measure the power and frequency of the detected IEMI high intensity signal. As illustrated in FIG. 1, in an embodiment, the multichannel detection unit 106 includes a threshold-based latch 122, a power detector 124 and a frequency detector 126. These components receive the RF signals from the front-end unit 104 in parallel so that the same RF signal can be processed by these components. In an embodiment, the RF signals are transmitted from the frond-end unit 103 as multiple parallel RF signals to the threshold-based latch 122, the power detector 124 and the frequency detector 126 of the multichannel detection unit 106. In this embodiment, the frond-end unit 104 is designed to separate the input RF signals to multiple parallel RF signals for processing.

The threshold-based latch 122 operates to monitor the signal strength of received RF signals during a monitoring mode. If the signal strength of an RF signal exceeds a preset threshold level, the threshold-based latch 122 then latches a binary output to a particular output, e.g., a high output signal, which is transmitted to the processor 112 via the digitizer 108 for processing. Once latched, the output of the threshold-based latch 122 remains at the particular output. The threshold-based latch 122 needs to be reset for the threshold-based latch to go back to the monitoring mode.

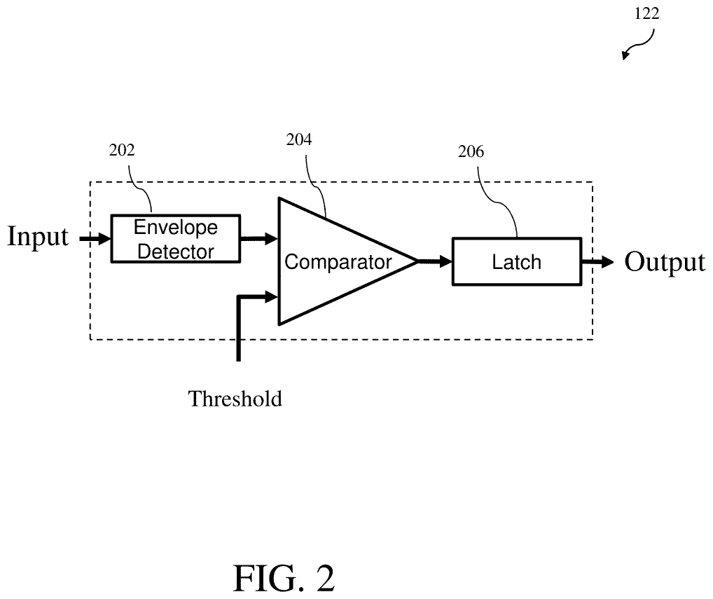

FIG. 2 is a block diagram of the threshold-based latch 122 in accordance with an embodiment of the invention. As shown in FIG. 2, the threshold-based latch 122 includes an envelope detector 202, a comparator 204 and a latch 206. The envelope detector 202 down converts the input RF signal to low frequency or DC. As used herein, a “low frequency” signal is considered to be a signal with frequency ranging from ELF (extremely low frequency) to LF (low frequency) band, as defined by the International Telecommunication Union (ITU). The comparator 204 compares the level of the down-converted signal with a preset value, which is provided by a threshold signal. If the signal level exceeds the preset value, the latch 206 outputs a particular output signal, e.g., a high output signal, to indicate detection of a signal. The output state stays on until user resets the threshold-based latch 122. The threshold-based latch 122 may be implemented as a discrete circuit or an integrated circuit (IC).

The power detector 124 operates to measure the power (or field strength) of the received RF signals. In an embodiment, the power detector 124 is a characterized RF to low frequency converter which can down convert the frequency of the signal for ease of digitization and to detect the power of a narrowband signal. The power detector 124 can also be used to detect transient (broadband) signal in uncharacterized mode. The output of the power detector is available as long as a signal is detected (e.g., the threshold-based latch 122 is latched to the particular output). The threshold-based latch output stays on if a signal is detected momentarily. However, the power detector 124 only stays on when the signal is present. Thus, as soon as the signal is turned off, the power detector output turns off. The measured power of the signal is transmitted to the processor 112 via the digitizer 108 for processing.

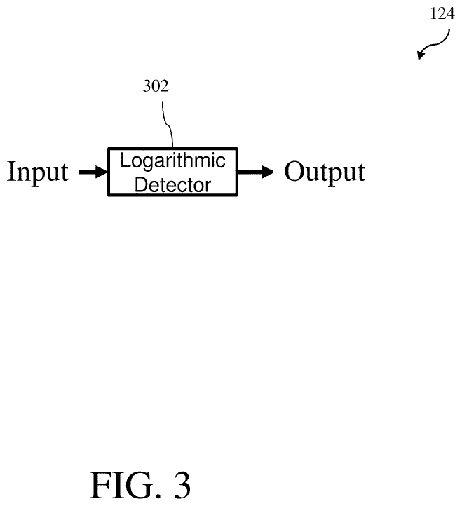

FIG. 3 is a block diagram of the power detector 124 in accordance with an embodiment of the invention. As shown in FIG. 3, the power detector 124 includes a logarithmic detector 302, which outputs an output signal of DC voltage in response to an RF input signal that indicates the power of the input signal. The power detector 124 may be implemented as a discrete circuit or an integrated circuit (IC).

The frequency detector 126 operates to detect the frequency of the received RF signals. In an embodiment, the frequency detector 126 is a characterized RF to low frequency converter to detect the frequency of a narrowband signal. The frequency detector 126 can also be used to detect transient (broadband) signals in uncharacterized mode. The output of the frequency detector 126 is available as long as a signal is detected (e.g., the threshold-based latch 122 is latched to the particular output). Similar to the power detector 124, the frequency detector 126 only stays on when the signal is present. Thus, as soon as the signal is turned off, the frequency detector output turns off. The output of the frequency detector 126 is transmitted to the processor 112 via the digitizer 108 for processing.

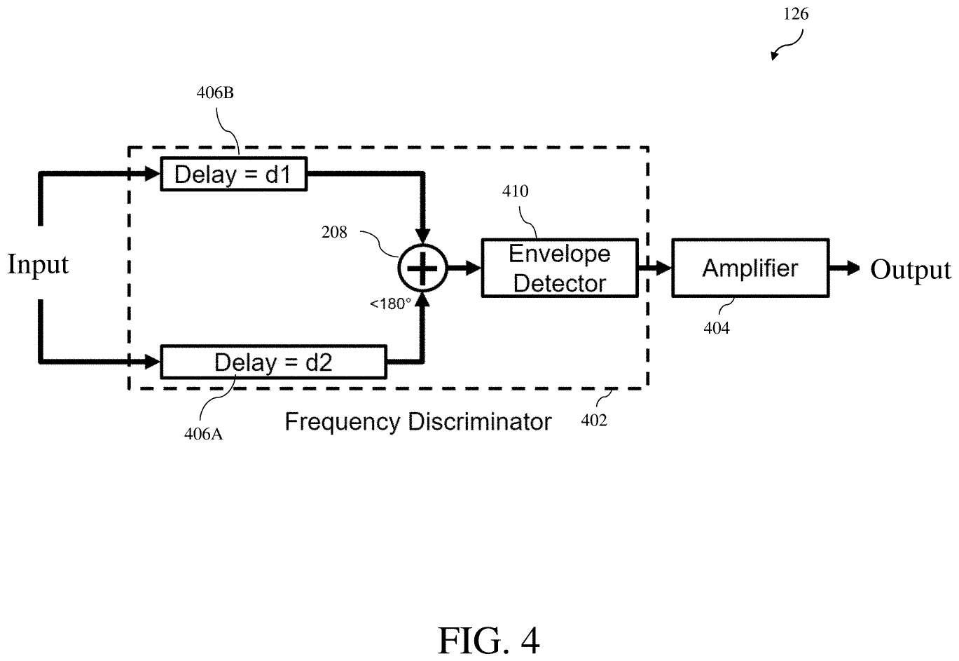

FIG. 4 is a block diagram of the frequency detector 126 in accordance with an embodiment of the invention. As shown in FIG. 4, the frequency detector 126 includes a frequency discriminator 402 and an amplifier 404. The frequency discriminator 402 includes two transmission lines 406A and 406B, an RF hybrid 408 and an envelope detector 410. The two transmission lines 406A and 406B are geometrically designed to have different line delays. The RF hybrid 408 operates to add the two signals with 180 degree phase shift. The envelope detector 410 operates to convert the RF signal to low frequency (or DC) for ease of digitization. The resulting signal is then sent to the amplifier 404 to increase the dynamic range of the frequency detector 126. The output of the amplifier 404 is the output of the frequency detector 126.

Turning back to FIG. 1, the digitizer 108 operates to receive the analog signals from the threshold-based latch 122, the power detector 124 and the frequency detector 126 of the multichannel detection unit 106 and converts them in to digital signals, which are transmitted to the processor 112 for processing. As an example, the digitizer 108 may include a number of analog-to-digital converters to digitize the received signals from the multichannel detection unit 106.

The processor 112 acquires the data, i.e., digitized signals, from all the detectors of the multichannel detection unit 106 and executes at least one task based on the data. The tasks may include (a) based on an algorithm, decide whether the detected signal is an actual IEMI high intensity signal or is a false alarm, (2) activate the alarm 118 if an actual IEMI high intensity signal is detected, (c) communicate with the external control unit 116 to inform the users about the IEMI high intensity signal, and (d) control the MIDC system 100 and reset the system if needed and logs the IEMI event (i.e., signal detected) and its characteristics. The alarm 118 can be any type of device that can produce audio and/or visual alerts.

In an embodiment, all processing may be done locally on the processor 112. In this embodiment, the external control unit 116 may not be required. In another embodiment, data is communicated remotely via a communication link 128 (such as wireless, wired, or optical, etc.) to the external control unit 116, which may be a personal computer, to process the data. In this embodiment, the processor 112 may simply prepare the digital signals from the digitizer 108 for transmission to the external control unit 116 via the communication link 128. If both are used for processing, the processor 112 and the external control unit 116 may share the processing and communicate with each other via the communication link 128.

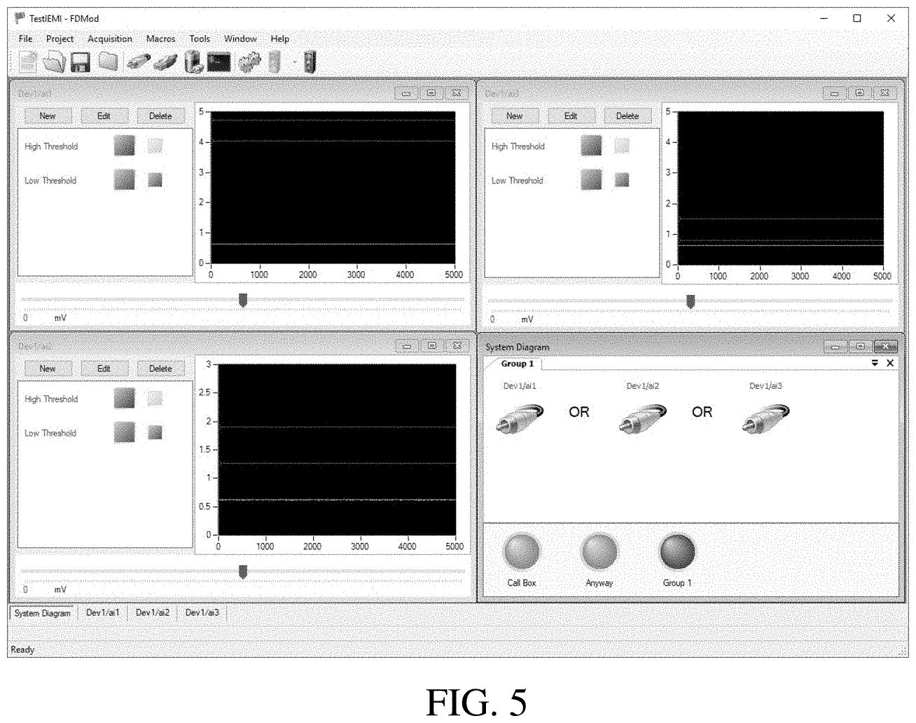

In an embodiment, the control unit 116 may use software that provides a graphical user interface for a user to control the MIDC system 100 and to see the information regarding any IEMI high intensity signal detected by the system. FIG. 5 is a screenshot of the graphical user interface provided by the software installed and running on the control unit 116. The graphical user interface includes tools to review the logging of IEMI events and their characteristics such as frequency, magnitude, repetition rate, duration, bandwidth, etc. Additionally, the graphical user interface may be used to set the parameters such as magnitude threshold for detection and to reset the detector.

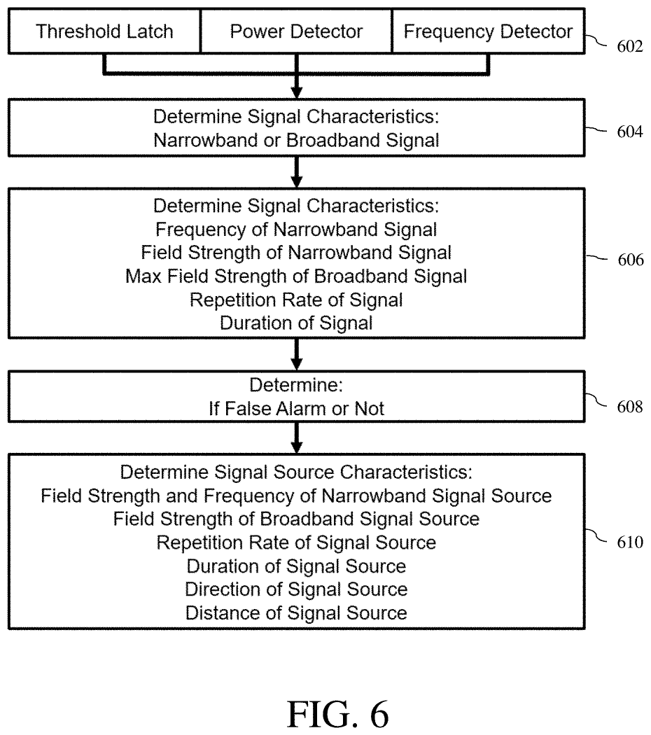

The detection, characterization and localization operations of the MIDC system 100 in accordance with an embodiment of the invention are described with reference to a flowchart of FIG. 6. In this embodiment, it is assumed that all the processing is performed by the external control unit 116. However, as previously explained, the processing may be performed by the processor 112 and/or the control unit 116.

At block 602, when a potential IEMI high intensity signal is detected, i.e., the threshold-based latch 122 produces a particular output, the output of the threshold-based latch 122, the power detector 124 and the frequency detector 124 of the multichannel detection unit 106 are transmitted to the external control unit 116 for processing. Next, at block 604, the signal type of the detected signal is determined by the control unit 116. That is, it is determined whether the detected signal is a narrowband signal or a broadband signal.

Next, at block 606, other characteristics of the detected signal are determined by the control unit 116. As an example, the frequency and field strength of narrowband signals, the maximum field strength of broadband (transient) signals, repetition rate, and duration of signal may be determined by the control unit 116. In addition, the statistical data can be recorded by the control unit 116, such as how frequent, how long, and what time of the day the signal appears. Next, at block 608, the characteristics and statistical data are used by the control unit 116 to determine if the detected signal is a false alarm (such as a nearby radio communication station, an emergency vehicle communication, a radar signal from a nearby airport, etc.) or an IEMI high intensity signal. Many of IEMI events happen as a train of pulses and the repetition rate in conjunction with power, frequency, and bandwidth can be used to distinguish IEMI events from false alarms.

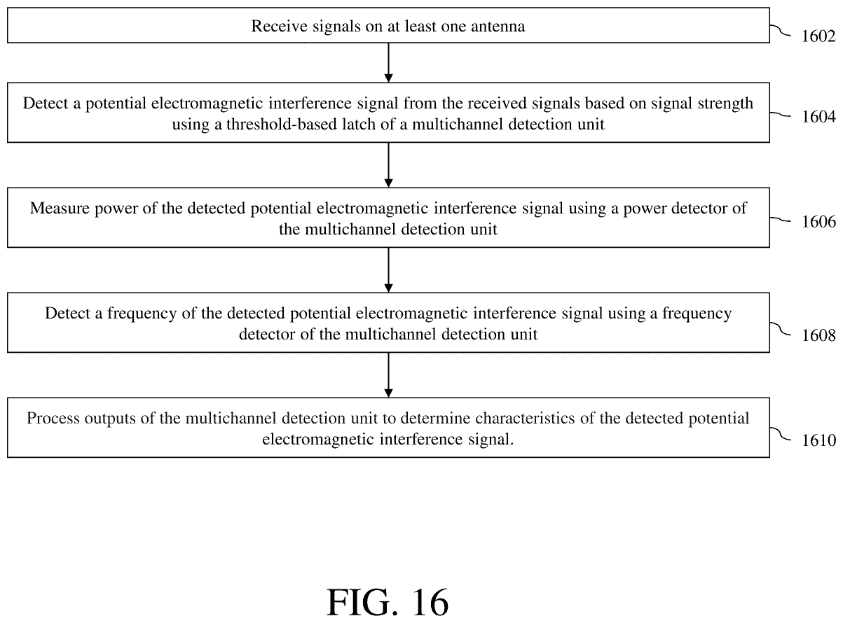

Next, at block 610, if an array antenna system (see FIG. 16) is used, signal source characteristics may be determined by the control unit 116. As an example, the field strength and frequency of a narrowband signal source, the field strength of a broadband signal source, the repetition rate of a signal source, the duration of a signal source, the direction of a signal source and/or distance of a signal source may be determined by the control unit 116. Array processing techniques such as phased arrays and beamforming can be utilized to process the data from multiple antenna channels for the source localization.

Individual detection channels of the IEMI detector 120 can be characterized for narrowband and broadband response at test facilities. For the sake of these characterizations, the EMI-shielded box 114 may be removed for ease of characterization.

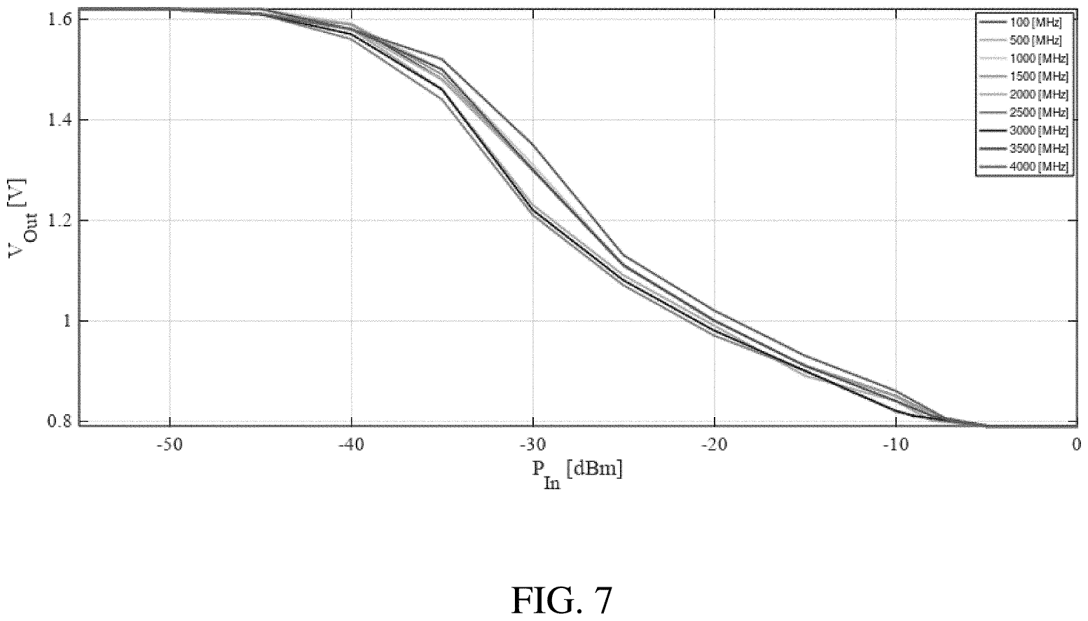

The power detector channel is characterized for its narrowband response. The power channel is excited directly using a signal generator at discrete frequency points from 100 MHz to 4 GHz and the output steady state voltage of the channel is measured using an oscilloscope. At each frequency point, the input power level is swept from −55 dBm to 0 dBm. FIG. 7 shows the narrowband response of the power detector channel. As shown in FIG. 7, the dynamic range of the power detector 124 is about 45 dB with about 3 dB tolerance.

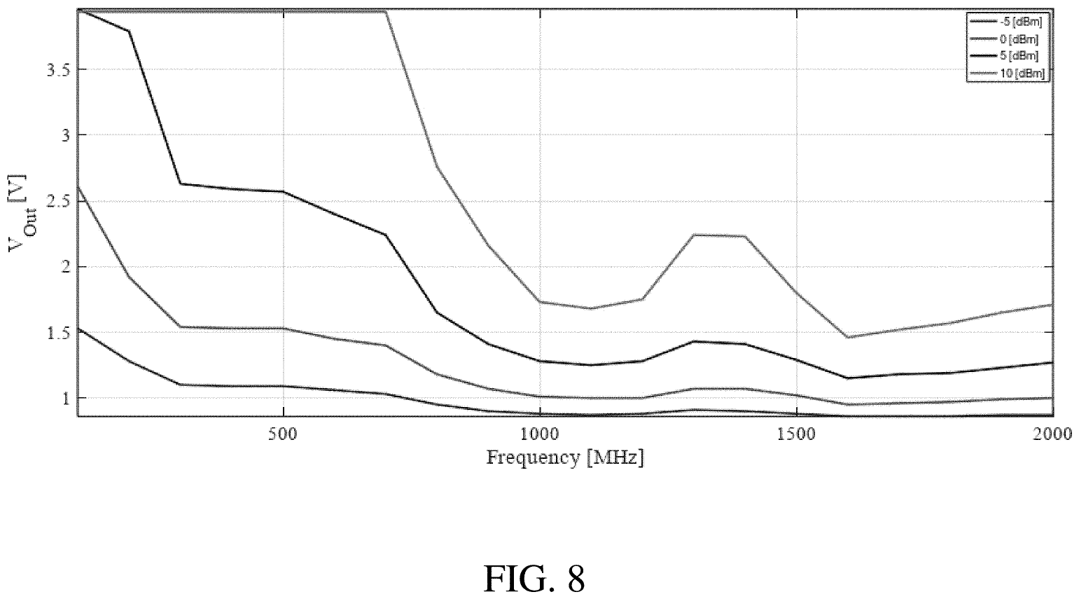

The frequency detector channel is characterized for its narrowband response. The frequency channel is excited directly using a signal generator at discrete power points from −5 dBm to 10 dBm and the output steady state voltage of the channel is measured using an oscilloscope. At each power point, the input frequency is swept from 100 MHz to 2 GHz. FIG. 8 shows the narrowband response of the frequency detector channel. FIG. 8 shows that the dynamic range is from 100 MHz to 1.7 GHz with about 200 MHz tolerance. The optimal dynamic range happens at +5 dBm input power. An automatic gain control (AGC) might be used in the RF front-end for signal conditioning to maintain the power at the optimal level.

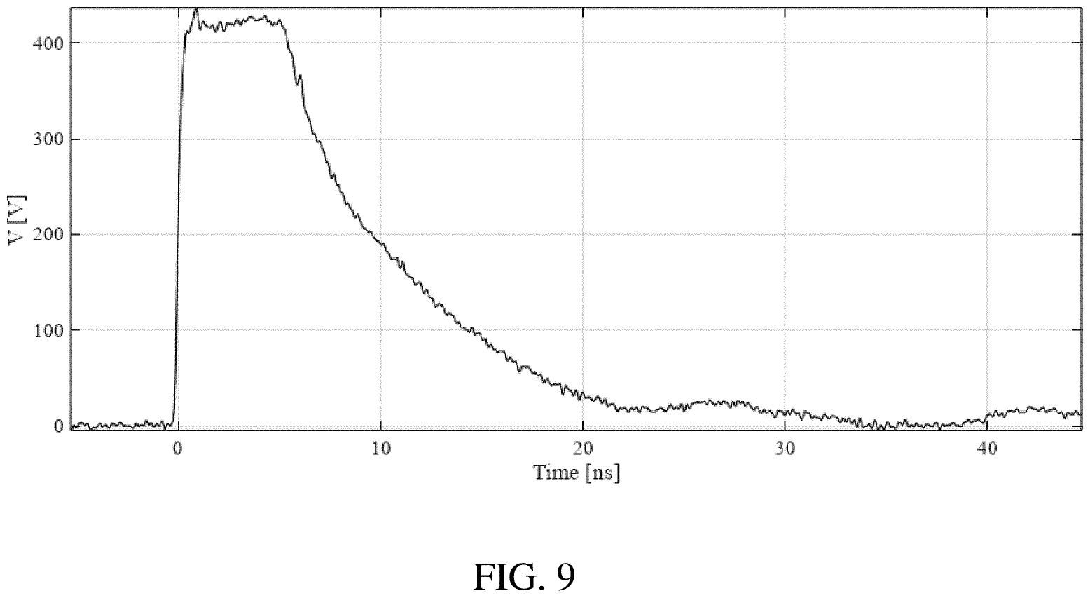

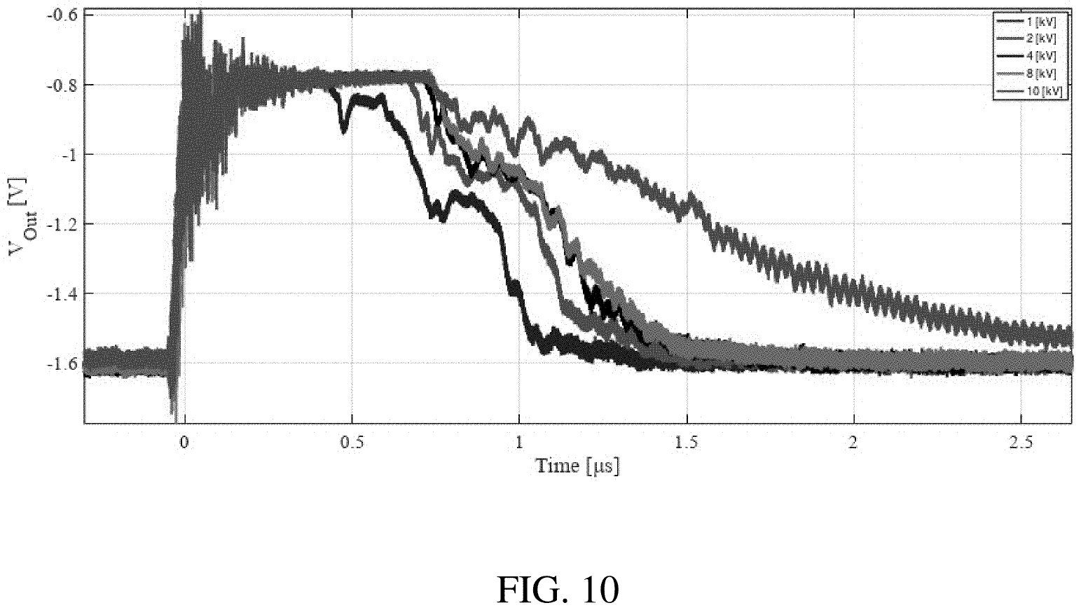

The power detector channel is also characterized for its broadband response. The power channel is excited using a transmission line pulser (TLP) through a pair of Rx-Tx log-periodic antennas at discrete voltage settings from 1 kV to 10 kV and the output transient voltage of the channel is measured using an oscilloscope. FIG. 9 shows the output voltage of the TLP when connected to a matched load. FIG. 10 shows the broadband response of the power detector channel. FIG. 10 shows that the pulse width is monotonically increasing as a function of field strength. The pulse width varies from 0.5 μs to 0.75 μs. However, the increase rate is not linear and may not be optimal for characterization.

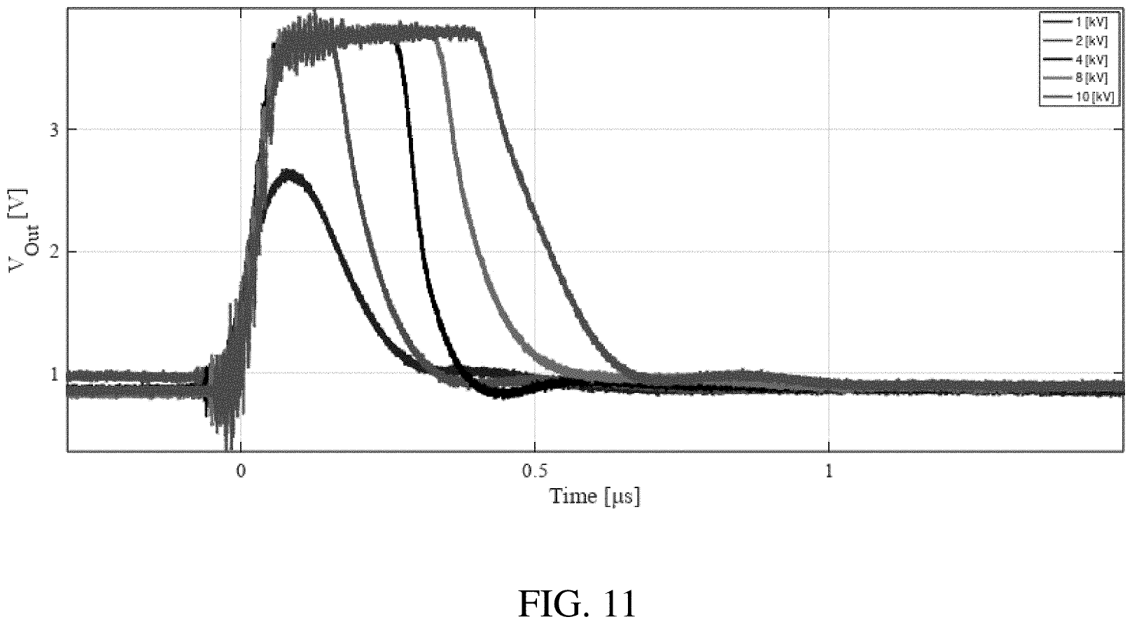

The frequency detector channel is also characterized for its broadband response. The frequency channel is excited using a TLP through a pair of Rx-Tx log-periodic antennas at discrete voltage settings from 1 kV to 10 kV and the output transient voltage of the channel is measured using an oscilloscope. FIG. 11 shows the broadband response of the frequency detector channel. FIG. 11 shows that the pulse width is monotonically increasing as a function of field strength. The pulse width varies from 0.1 μs to 0.4 μs. The increase rate is more linear compared to power detector and may be used for characterization of peak magnitude of some transient signals.

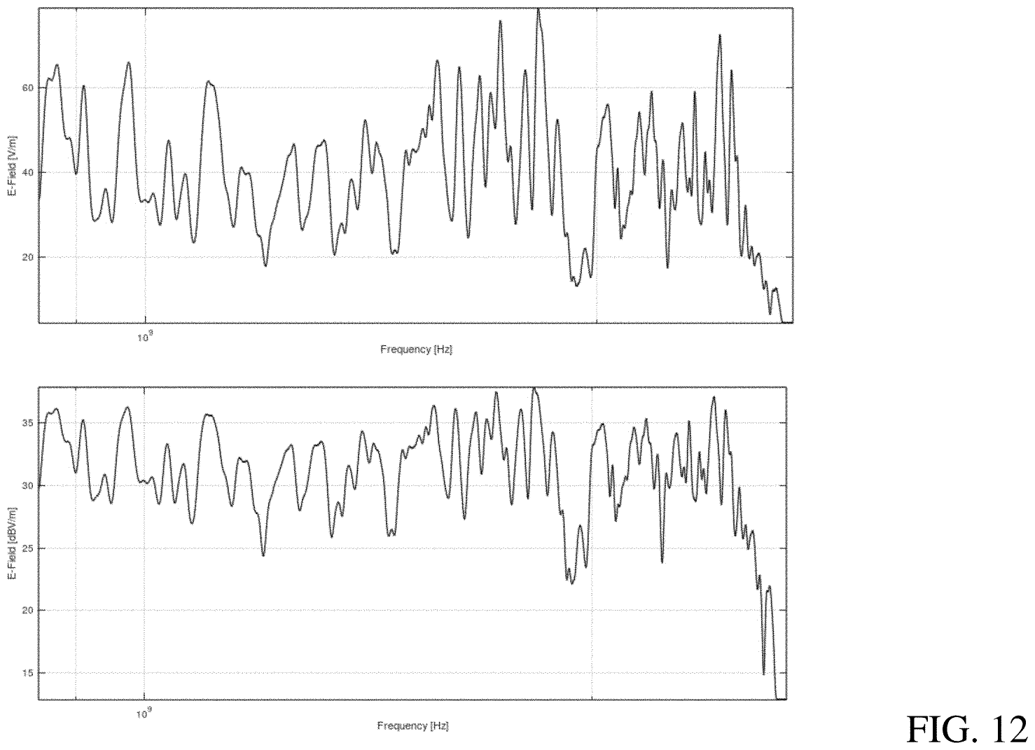

All channels of the IEMI detector 120 were tested for detection capability as well as immunity to high intensity field at test facilities. For the narrowband signal, the IEMI detector 120 was excited both conductively as well as using radiation through Tx-Rx pair of antennas. In the conducted case, the frequency was swept from 100 MHz to 4 GHz and the power was swept from −5 dBm to 10 dBm. In the radiated case, the frequency was swept from 850 MHz to 2.7 GHz. The maximum exposure field strength is shown in FIG. 10. The top graph in FIG. 12 shows the electric field strength in linear scale (V/m), while the bottom graph in FIG. 12 shows the electric field strength in logarithmic scale (dBV/m). Under all conditions, all three channels of the IEMI detector 120 were capable of detecting and registering the signal. Under all test conditions, no degradation of performance, hard, or soft failure was observed during any of the test evens when IEMI detector 120 had long exposure (several minutes) to high field values.

Three test configurations were used for the broadband detection capabilities. In the first test configuration, the TLP was connected to LP8565 log-periodic antenna (850 MHz to 6.5 GHz). The IEMI detector was placed at 1 m away from the aggressor antenna. The voltage setting of the TLP was increased from 1 kV to 10 kV. The output pulse rate was swept from 1 to 100 pulses per second.

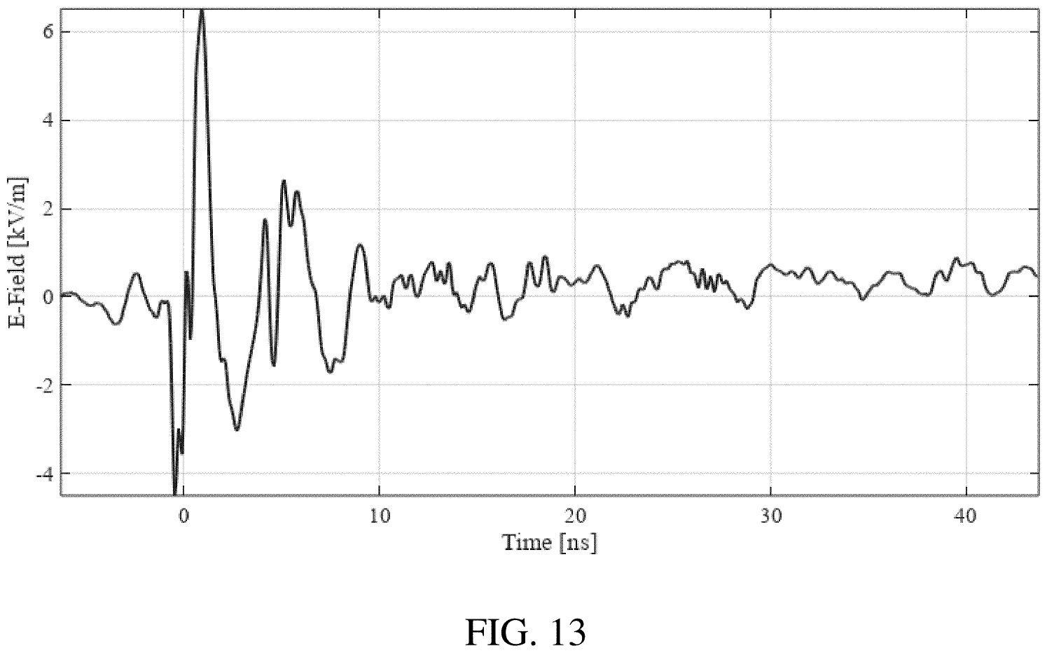

In the second test configuration, the TLP was connected to SAS-570-7/16 double-ridge horn antenna (170 MHz to 3 GHz). The TLP voltage setting was set at 8 kV. The IEMI detector was placed 20 cm away from the antenna aperture. The E-field in this test configuration was measured at the detector location. The measured E-field is shown in FIG. 13.

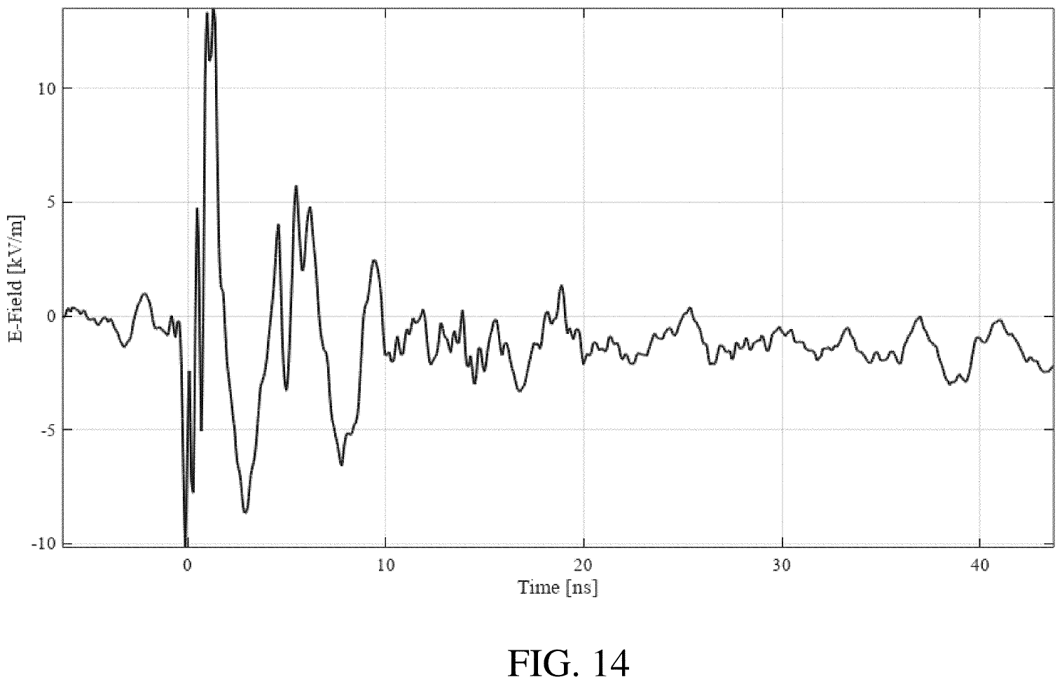

In the third test configuration, Kentech Instruments PBG1-D pulse generator was connected to the double-ridge horn antenna. The peak transient E-field was changed from ˜2 kV/m to ˜13 kV/m. The transient E-field at 13 kV/m is shown in FIG. 14. The generator was excited with single pulse as well as 100 pulses per second.

Under all test conditions, the IEMI detector 120 was capable of detecting and registering the transient pulse. Under all test conditions, no degradation of performance, hard, or soft failure was observed during any of the tests even when IEMI detector 120 had long exposure (several minutes) to high field values. The maximum peak-to-peak voltage at the RF entry point to the IEMI detector 120 (after Rx antenna) was measured as 203 V. In another test scenario, the IEMI detector power cord (˜1 m long) was exposed to 13 kV/m field for 3 minutes. No degradation of performance, hard, or soft failure was observed.

To find the location of the signal source, multiple antennas are required for signal acquisition. An array of antennas in conjunction with signal processing techniques can determine the direction and/or the distance of the source from the receive antenna. Processing techniques for phased array antennas such as direction of arrival (DOA) or beamforming can be used for localization. Additionally, the localization technique can be used to reduce false alarm rate.

A set of electric fast transient (EFT) tests was also performed to test the robustness of the power entry to fast transient pulses at Metatech test facilities. A Haefley P90.1 control unit, PEFT.1 burst tester, and PHV141.2 HV unit were used for these tests. The pulse was injected between line and ground as well as neural and ground wires of the power port of the IEMI detector. The voltage setting on the EFT generator was changed from 500 V to 4.5 kV. No hard failure was observed during any stage of the test. Under one condition (with 3 kV setting on EFT and differential injection between neutral and ground), the threshold-based latch channel registered a false alarm. The transient current injected into each line was monitored for reference.

An exposure and detection scenario was demonstrated in an electromagnetic shielded room at Amber Precision Instruments Inc.'s (API) test facilities. The IEMI detector 120 was placed close to a commercial-off-the-shelf (COTS) personal computer (PC) connected to a COTS LCD monitor. The PC and monitor were representing the victim components of an IEMI signal. The aggressor antenna was placed 1 m away from the victim as well as the IEMI detector. It was observed that the PC and monitor operation froze and the monitor went black when exposed to narrowband field of ˜50 V/m at 900 MHz. A PC reset was required for recovery. The IEMI detector was actively monitoring the environmental noise. Once the high intensity burst occurred, the PC and monitor failed and simultaneously the IEMI detector registered the signal through its software and the software-defined indicator turns from green to red. The software recorded the output values of the channels to be calibrated to magnitude and frequency of the signal. The alarm LED indicators on the IEMI detector 120 started blinking red as a result of signal detection. The below table lists the instruments used for this scenario.

| Item # | Description | Model |
|---|---|---|
| 1 | IEMI Detector Board | API IEMI Detector |
| 2 | Data Acquisition (DAQ) | National Instruments |
| 3 | Detection Software | API SmartScan-FD |
| 4 | Rx Antenna | Log-periodic LP8565: 850 |
| | | to 6500 MHz |
| 5 | Signal Generator | Agilent 8648D |
| | (Narrowband Aggressor) | |
| 6 | Power Amplifier | Mini-circuit: 50 dB gain, |
| | (Narrowband Aggressor) | 30 W, 700 to 2700 MHz |
| 7 | Tx Antenna (Aggressor) | Log-periodic LP8565: 850 |
| | | to 6500 MHz |
| 8 | Victim | PC + Monitor |

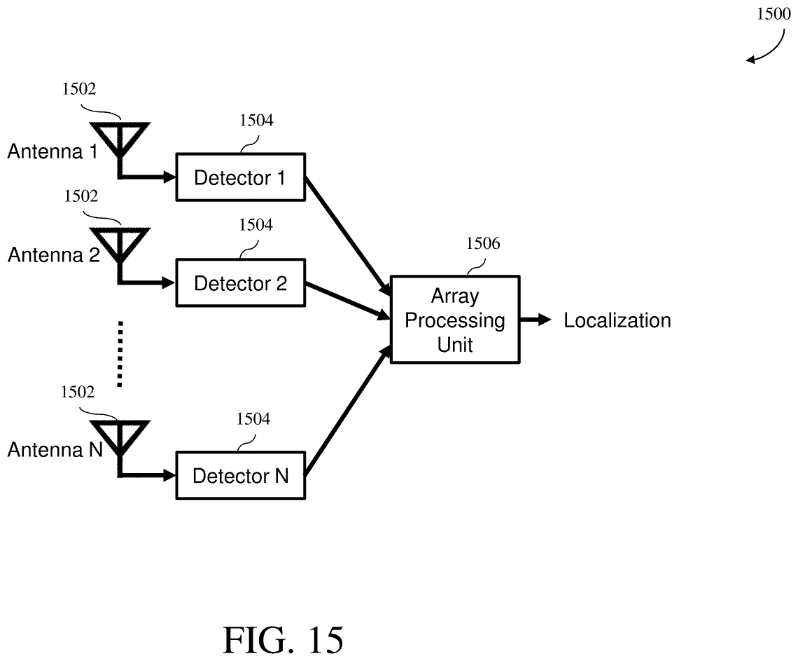

Turning now to FIG. 15, a block diagram of an antenna array system 1500 for source localization in accordance with an embodiment of the invention is shown. The array system 1500 includes an array of antennas 1502 individually connected to a signal detector 1504. The detector type can be any of the detectors described above in this disclosure. The output of the detectors 1504 is connected to an array processing unit 1506 which digitizes the input signals and processes multiple channels to find the location of the source of the high intensity electromagnetic interference signal. The array processing techniques may be any of well-known beamforming or phased array signal processing methodologies.

A method for detecting and characterizing high intensity electromagnetic interference signals, which may be intentional or unintentional electromagnetic interference signals, in accordance with an embodiment of the invention is described with reference to a flow diagram of FIG. 16. At block 1602, signals are received on at least one antenna. At block 1604, a potential electromagnetic interference signal from the received signals is detected based on signal strength using a threshold-based latch of a multichannel detection unit. At block 1606, power of the detected potential electromagnetic interference signal is measured using a power detector of the multichannel detection unit. At block 1608, a frequency of the detected potential electromagnetic interference signal is detected using a frequency detector of the multichannel detection unit. At block 1610, outputs of the multichannel detection unit are processed to determine characteristics of the detected potential electromagnetic interference signal.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

It should also be noted that at least some of the operations for the methods may be implemented using software instructions stored on a computer useable storage medium for execution by a computer. As an example, an embodiment of a computer program product includes a computer useable storage medium to store a computer readable program that, when executed on a computer, causes the computer to perform operations, as described herein.

Furthermore, embodiments of at least portions of the invention can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

The computer-useable or computer-readable medium can be an electronic, magnetic, optical, electromagnetic, infrared, or semiconductor system (or apparatus or device), or a propagation medium. Examples of a computer-readable medium include a semiconductor or solid state memory, magnetic tape, a removable computer diskette, a random access memory (RAM), a read-only memory (ROM), a rigid magnetic disc, and an optical disc. Current examples of optical discs include a compact disc with read only memory (CD-ROM), a compact disc with read/write (CD-R/W), a digital video disc (DVD), and a Blu-ray disc.

In the above description, specific details of various embodiments are provided. However, some embodiments may be practiced with less than all of these specific details. In other instances, certain methods, procedures, components, structures, and/or functions are described in no more detail than to enable the various embodiments of the invention, for the sake of brevity and clarity.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A high intensity electromagnetic interference detection system comprising:
at least one antenna to receive signals;
a multichannel detection unit connected to the at least one antenna to receive the signals, the detection unit including:
a threshold-based latch to detect a potential electromagnetic interference signal from the received signals based on signal strength;
a power detector to measure power of the detected potential electromagnetic interference signal; and
a frequency detector to detect a frequency of the detected potential electromagnetic interference signal; and
a processor connected to the multichannel detection unit to receive outputs from the multichannel detection unit and process the outputs to determine characteristics of the detected potential electromagnetic interference signal.

2. The electromagnetic interference detection system of claim 1, wherein the frequency detector comprises a frequency discriminator that includes transmission lines with different delays that are connected to a radio frequency (RF) hybrid that is configured to add signals on the transmission lines with 180 degree phase shift.

3. The electromagnetic interference detection system of claim 2, wherein the frequency detector further comprises an envelope detector connected to the RF hybrid to convert an RF signal from the radio frequency to low frequency or DC.

4. The electromagnetic interference detection system of claim 1, wherein the processor is programmed to decide whether the detected potential electromagnetic interference signal is a high intensity electromagnetic interference signal or is a false alarm based on one or more characteristics of the detected potential electromagnetic interference signal.

5. The electromagnetic interference detection system of claim 4, wherein the processor is programmed to activate an alarm when the detected potential electromagnetic interference signal is determined to be a high intensity electromagnetic interference signal.

6. The electromagnetic interference detection system of claim 4, wherein the processor is programmed to log the detection of the potential electromagnetic interference signal as an electromagnetic interference event and log characteristics of the detected potential electromagnetic interference signal.

7. The electromagnetic interference detection system of claim 6, wherein the characteristics of the detected potential electromagnetic interference signal that are logged include frequency, magnitude, bandwidth and repetition rate.

8. The electromagnetic interference detection system of claim 1, further comprising an electromagnetic interference-shielded box in which at least the multichannel detection unit is located.

9. The electromagnetic interference detection system of claim 8, wherein the processor is located within the electromagnetic interference-shielded box.

10. A method for detecting and characterizing high intensity electromagnetic interference signals, the method comprising:
receiving signals on at least one antenna;
detecting a potential electromagnetic interference signal from the received signals based on signal strength using a threshold-based latch of a multichannel detection unit;
measuring power of the detected potential electromagnetic interference signal using a power detector of the multichannel detection unit;
detecting a frequency of the detected potential electromagnetic interference signal using a frequency detector of the multichannel detection unit; and
processing outputs of the multichannel detection unit to determine characteristics of the detected potential electromagnetic interference signal.

11. The method of claim 10, wherein detecting the frequency of the detected potential electromagnetic interference signal includes using transmission lines with different delays that are connected to a radio frequency (RF) hybrid that is configured to add signals on the transmission lines with 180 degree phase shift.

12. The method of claim 11, wherein detecting the frequency of the detected potential electromagnetic interference signal further comprises using an envelope detector connected to the RF hybrid to convert an RF signal from the radio frequency to low frequency or DC.

13. The method of claim 10, wherein processing the outputs of the multichannel detection unit includes deciding whether the detected potential electromagnetic interference signal is a high intensity electromagnetic interference signal or is a false alarm based on one or more characteristics of the detected potential electromagnetic interference signal.

14. The method of claim 13, wherein processing the outputs of the multichannel detection unit includes activating an alarm when the detected potential electromagnetic interference signal is determined to be a high intensity electromagnetic interference signal.

15. The method of claim 13, wherein processing the outputs of the multichannel detection unit includes logging the detection of the potential electromagnetic interference signal as an electromagnetic interference event and logging characteristics of the detected potential electromagnetic interference signal.

16. The method of claim 15, wherein the characteristics of the detected potential electromagnetic interference signal that are logged includes frequency, magnitude, bandwidth and repetition rate.

17. The method of claim 10, wherein the multichannel detection unit is located within an electromagnetic interference-shielded box.

18. The method of claim 17, wherein a processor that executes the processing of the outputs of the multichannel detection unit is located within the electromagnetic interference-shielded box.
